(19) United States
(12) Patent Application Publication
(10) Pub. No.: US 2022/0112600 A1
(43) Pub. Date: Apr. 14, 2022

(54) METHOD OF DEPOSITING THIN FILMS USING PROTECTIVE MATERIAL

(71) Applicant: EGTM Co., Ltd., Suwon-si (KR)

(72) Inventors: Jae Min KIM, Suwon-si (KR); Ha Na KIM, Suwon-si (KR); Woong Jin CHOI, Suwon-si (KR); Ji Yeon HAN, Suwon-si (KR); Ha Joon KIM, Suwon-si (KR)

(73) Assignee: EGTM Co., Ltd., Suwon-si (KR)

(21) Appl. No.: 17/496,439

(22) Filed: Oct. 7, 2021

(30) Foreign Application Priority Data
Oct. 8, 2020 (KR) 10-2020-0129773

(51) Int. Cl. C23C 16/455; C23C 16/52

(52) U.S. Cl. CPC C23C 16/45527; C23C 16/52; C23C 16/45553; C23C 16/45544

(57) ABSTRACT

Disclosed is a method of forming a thin film using a surface protection material, the method comprising supplying the surface protection material to the inside of a chamber on which a substrate is placed; purging the interior of the chamber; supplying a doping precursor to the inside of the chamber; purging the interior of the chamber; supplying a first reactant to the inside of the chamber so that the first reactant reacts with the adsorbed doping precursor to form a doping thin film; supplying a dielectric film precursor to the inside of the chamber; purging the interior of the chamber; and supplying a second reactant to the inside of the chamber so that the second reactant reacts with the adsorbed dielectric film precursor to form a dielectric film.

### TECHNICAL FIELD

The present invention relates to a method of depositing thin films. More particularly, the present invention relates to method of depositing thin films having a very thin thickness, so that the thickness of a dielectric film and the composition in the dielectric film can be easily controlled, thereby realizing a desired composition ratio and improving a dielectric constant of the thin film.

### BACKGROUND

With changes such as high integration and low power consumption of memory/non-memory semiconductor devices such as DRAM and Flash, the need for forming a dielectric thin film with excellent characteristics is deepening.

For example, zirconium oxide (ZrO2) and hafnium oxide (HfO2), which have a high dielectric constant even at a very thin thickness, are applied as a capacitor dielectric layer. Zirconium oxide (ZrO2) and hafnium oxide (HfO2) exist in various crystal structures depending on the temperature and pressure, and the capacitance varies according to the structure. Tetragonal zirconium oxide (ZrO2) and cubic or tetragonal hafnium oxide (HfO2) are known to have more than twice the capacitance compared to other structures, but in general, monoclinic phase is stable at room temperature and pressure.

Accordingly, many studies have been made to obtain a high dielectric constant by stabilizing the zirconium oxide and hafnium oxide crystal structures by doping. However, doping causes deterioration of dielectric properties and leakage current due to local compositional non-uniformity, and thus has many difficulties in application. Therefore, it is required to improve the capacitance according to the improvement of composition uniformity and crystallinity in the thin film, and it is necessary to develop a thin film depositing method with improved step coverage.

An object of the present invention is to provide a method of depositing thin films, which have a very thin thickness.

Another object of the present invention is to provide a method of depositing thin films, so that a desired composition ratio can be realized by easily controlling the composition in the thin films, and thereby improving the dielectric constant.

Another object of the present invention is to provide a method of depositing thin films, so that an excellent semiconductor device is provided by forming the thin films having good step coverage while improving crystallinity.

Other objects of the present invention will become more apparent from the following detailed description.

### SUMMARY

Disclosed is a method of forming a thin film using a surface protection material, the method comprising supplying the surface protection material to the inside of a chamber on which a substrate is placed; purging the interior of the chamber; supplying a doping precursor to the inside of the chamber; purging the interior of the chamber; supplying a first reactant to the inside of the chamber so that the first reactant reacts with the adsorbed doping precursor to form a doping thin film; supplying a dielectric film precursor to the inside of the chamber; purging the interior of the chamber; and supplying a second reactant to the inside of the chamber so that the second reactant reacts with the adsorbed dielectric film precursor to form a dielectric film.

The surface protection material may be represented by the following Chemical Formula 1:

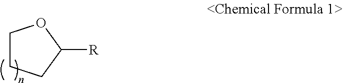

wherein n is 1 or 2, and R is selected from a hydrogen atom, an alkyl group having 1 to 5 carbon atoms, a cycloalkyl group having 3 to 6 carbon atoms, and an aryl group having 6 to 12 carbon atoms.

The surface protection material may be represented by the following Chemical Formula 2:

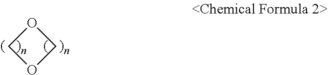

wherein n is each independently selected from an integer of 1 to 5.

The surface protection material may be represented by the following Chemical Formula 3:

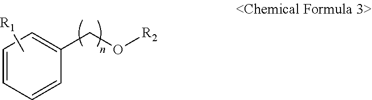

wherein n is each independently an integer from 0 to 8,

R1 is each independently selected from an alkyl group having 1 to 10 carbon atoms, an alkoxy group having 1 to 5 carbon atoms, or a hydrogen atom,

R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 4:

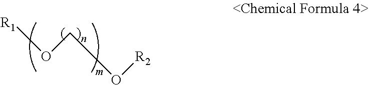

wherein n is each independently an integer from 1 to 8 and m is each independently an integer from 1 to 5,

R1 or R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 5:

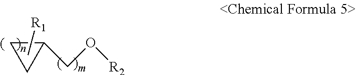

wherein n is each independently an integer from 1 to 5 and m is each independently an integer from 0 to 8,

R1 is each independently selected from an alkyl group having 1 to 8 carbon atoms, or a hydrogen atom,

R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 6:

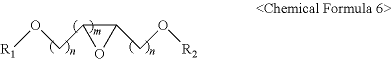

wherein n is each independently an integer from 1 to 8 and m is each independently an integer from 1 to 6,

R1 or R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 7:

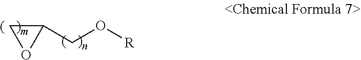

wherein n is each independently an integer from 0 to 5 and m is each independently an integer from 1 to 5,

R is each independently selected from an alkyl group having 1 to 10 carbon atoms, a cycloalkyl group having 3 to carbon atoms, and an aryl group having 6 to 12 carbon atoms.

The surface protection material may be represented by the following Chemical Formula 8:

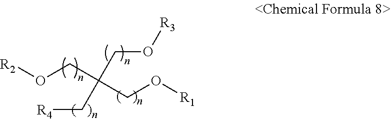

wherein n is each independently an integer from 0 to 8,

R1 to R3 are each independently selected from an alkyl group having 1 to 8 carbon atoms,

R4 is selected from a hydrogen, an alkyl group having 1 to 6 carbon atoms, and an alkoxy group having 1 to 8 carbon atoms.

The doping precursor may be represented by the following Chemical Formula 9:

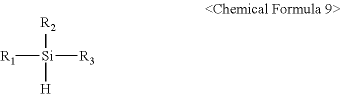

wherein R1 to R3 are each independently selected from a hydrogen atom, an alkyl group having 1 to 10 carbon atoms, an aryl group having 6 to 12 carbon atoms, an alkylamine group having 1 to 10 carbon atoms, a dialkyl amine group having 2 to 10 carbon atoms, aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

The doping precursor is represented by any one of the following Chemical Formulas 10 to 14:

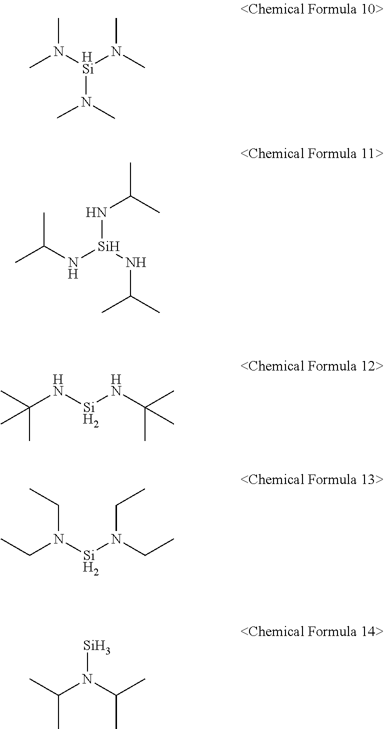

The doping precursor may be represented by the following Chemical Formula 15:

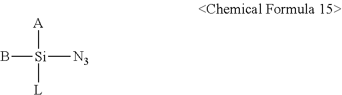

wherein A and B are each independently selected from a hydrogen atom, a halogen atom, an alkyl group having 1 to 10 carbon atoms, an aryl group having 6 to 12 carbon atoms, an alkylamine group having 2 to 10 carbon atoms, an arylamine group having 6 to 12 carbon atoms, and an aralkylamine group having 7 to 13 carbon atoms, a cyclic amine group having 3 to 10 carbon atoms, a heterocyclic amine group having 3 to 10 carbon atoms, and an alkyl silylamine group having 2 to 10 carbon atoms,

L is selected from a halogen atom, a hydrogen atom, or an azide group.

The doping precursor may be represented by any one of the following Chemical Formulas 16 to 21:

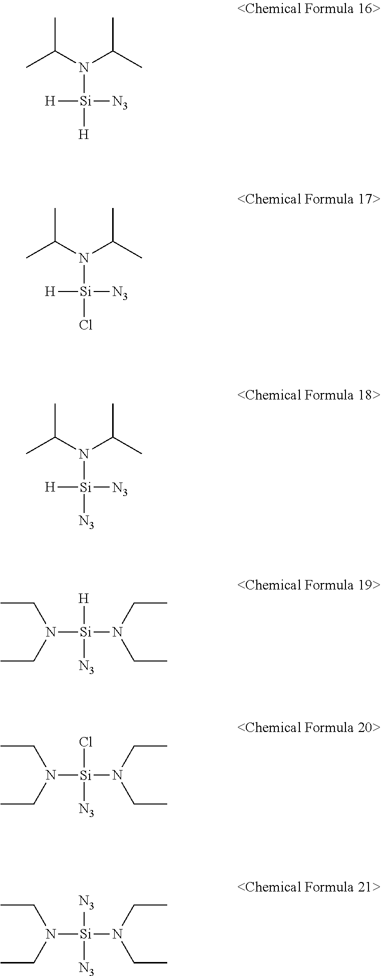

The doping precursor may be represented by the following Chemical Formula 22:

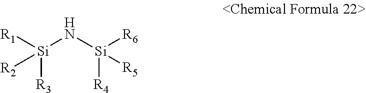

wherein R1 to R6 are each independently selected from a hydrogen atom, an alkyl group having 1 to 10 carbon atoms, an aryl group having 6 to 12 carbon atoms, an alkylamine group having 1 to 10 carbon atoms, an aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

The doping precursor may be represented by the following Chemical Formula 23:

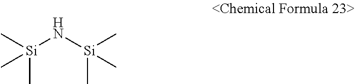

The doping precursor may be represented by the following Chemical Formula 24:

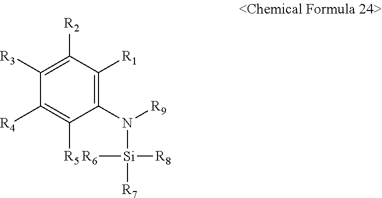

wherein R1 to R5 are each independently selected from a hydrogen atom, and an alkyl group having 1 to 4 carbon atoms,

R6 to R9 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

The doping precursor may be represented by any one of the following Chemical Formulas 25 to 27:

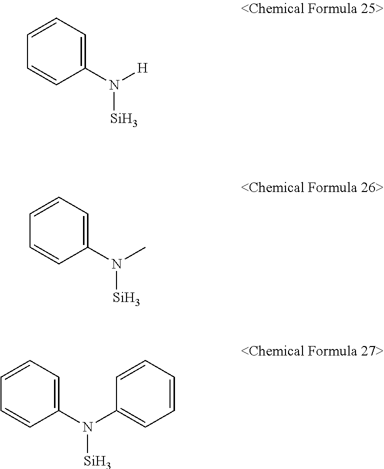

The doping precursor may be represented by the following Chemical Formula 28:

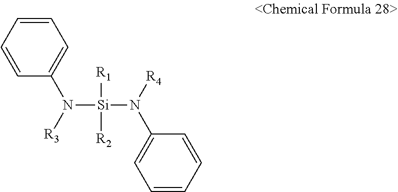

wherein R1 to R4 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

The doping precursor may be represented by the following Chemical Formula 29:

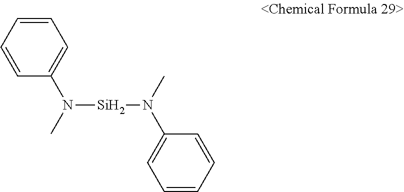

The first reactant and the second reactant may be selected from O₃, O₂, H₂O, H₂O₂, N₂O, and NH₃.

The dielectric film precursor may be a compound including at least one of a tetravalent metal containing Ti, Zr, and Hf.

### BRIEF DESCRIPTION OF THE DRAWINGS

FIG. 1 is a flowchart schematically demonstrating a method of forming a thin film according to an embodiment 1 of the present invention.

FIG. 2 is a graph schematically demonstrating a supply cycle according to the Comparative Example 1 of the present invention.

FIG. 3 is an X-ray diffraction (XRD) result of the thin film according to the Comparative Example 1 of the present invention.

FIG. 4 is a graph demonstrating secondary ion mass spectrometry (SIMS) for carbon of the thin film according to the Comparative Example 1 of the present invention.

FIG. 5 is a graph demonstrating secondary ion mass spectrometry (SIMS) for silicon of the thin film according to the Comparative Example 1 of the present invention.

FIG. 6 is a graph schematically demonstrating a supply cycle according to the embodiment 1 of the present invention.

FIG. 7 is an X-ray diffraction (XRD) result of the thin film according to the embodiment 1 of the present invention.

FIG. 8 is a graph demonstrating secondary ion mass spectrometry (SIMS) for carbon of the thin film according to the embodiment 1 of the present invention.

FIG. 9 is a graph demonstrating secondary ion mass spectrometry (SIMS) for silicon of the thin film according to the embodiment 1 of the present invention.

### DETAILED DESCRIPTION

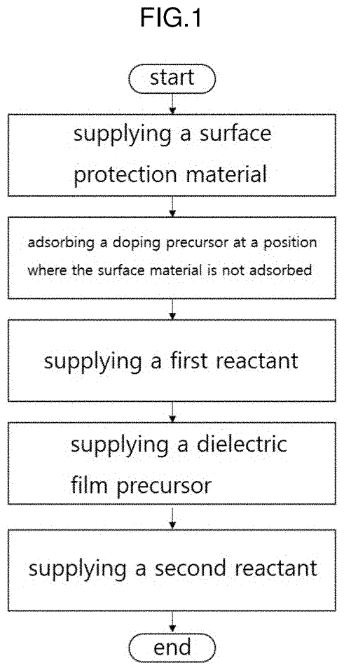

Hereinafter, embodiments of the present invention will be described using FIGS. 1 to 9. The embodiments of the present invention may include various modifications, and the scope of the present invention should not be construed to be limited to the embodiments described below.

FIG. 1 is a flowchart schematically demonstrating a method of forming a thin film according to an embodiment 1 of the present invention. A substrate is loaded into a process chamber, and following ALD process conditions are adjusted. ALD process conditions may include a temperature of the substrate or process chamber, a pressure in the process chamber, gas flow rate, and the temperature is 50 to 500° C.

The substrate is exposed to the surface protection material supplied to the interior of the chamber, and the surface protection material is adsorbed to the surface of the substrate. The surface protection material has a similar behavior to a doping precursor during the deposition process. The surface protection material forms a kind of suppression layer to prevent the adsorption of the doping precursor in a subsequent process, so that an island growth and the like are alleviated and a local compositional non-uniformity in a thin film formed thereafter is improved.

The surface protection material may be represented by the following Chemical Formula 1:

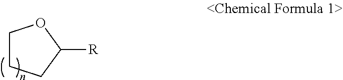

wherein n is 1 or 2, and R is selected from a hydrogen atom, an alkyl group having 1 to 5 carbon atoms, a cycloalkyl group having 3 to 6 carbon atoms, and an aryl group having 6 to 12 carbon atoms.

The surface protection material may be represented by the following Chemical Formula 2:

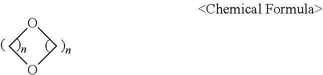

wherein n is each independently selected from an integer of 1 to 5.

The surface protection material may be represented by the following Chemical Formula 3:

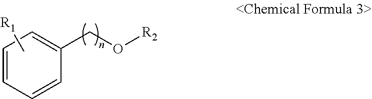

wherein n is each independently an integer from 0 to 8,

R1 is each independently selected from an alkyl group having 1 to 10 carbon atoms, an alkoxy group having 1 to 5 carbon atoms, or a hydrogen atom,

R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 4:

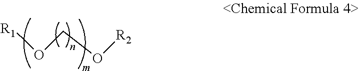

wherein n is each independently an integer from 1 to 8 and m is each independently an integer from 1 to 5,

R1 or R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 5:

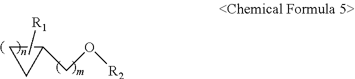

wherein n is each independently an integer from 1 to 5 and m is each independently an integer from 0 to 8,

R1 is each independently selected from an alkyl group having 1 to 8 carbon atoms, or a hydrogen atom,

R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 6:

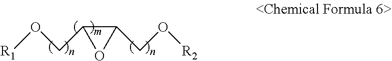

wherein n is each independently an integer from 1 to 8 and m is each independently an integer from 1 to 6,

R1 or R2 is each independently selected from an alkyl group having 1 to 8 carbon atoms, a cycloalkyl group having 3 to 6 carbon atoms, and an aryl group having 6 to 12 carbon atoms.

The surface protection material may be represented by the following Chemical Formula 7:

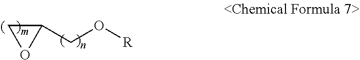

wherein n is each independently an integer from 0 to 5 and m is each independently an integer from 1 to 5,

R is each independently selected from an alkyl group having 1 to 10 carbon atoms, a cycloalkyl group having 3 to carbon atoms, and an aryl group having 6 to 12 carbon atoms.

The surface protection material may be represented by the following Chemical Formula 8:

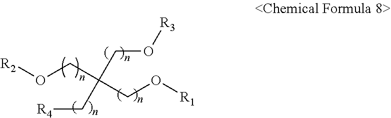

wherein n is each independently an integer from 0 to 8,

R1 to R3 are each independently selected from an alkyl group having 1 to 8 carbon atoms,

R4 is selected from a hydrogen, an alkyl group having 1 to 6 carbon atoms, and an alkoxy group having 1 to 8 carbon atoms.

Thereafter, a purge gas (for example, an inert gas such as Ar) is supplied to the interior of the chamber to discharge the unadsorbed surface protection material or by-products.

Thereafter, the substrate is exposed to a doping precursor supplied to the interior of the chamber, and the doping precursor is adsorbed on the surface of the substrate.

The doping precursor may be represented by the following Chemical Formula 9:

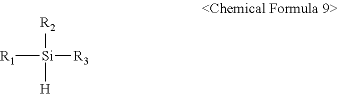

wherein R1 to R3 are each independently selected from a hydrogen atom, an alkyl group having 1 to 10 carbon atoms, an aryl group having 6 to 12 carbon atoms, an alkylamine group having 1 to 10 carbon atoms, a dialkyl amine group having 2 to 10 carbon atoms, aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

The doping precursor is represented by any one of the following Chemical Formulas 10 to 14:

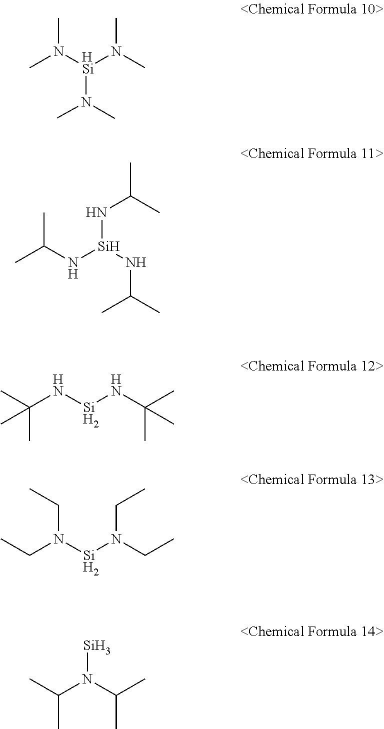

The doping precursor may be represented by the following Chemical Formula 15:

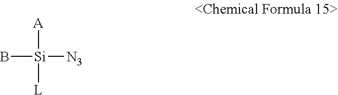

wherein A and B are each independently selected from a hydrogen atom, a halogen atom, an alkyl group having 1 to 10 carbon atoms, an aryl group having 6 to 12 carbon atoms, an alkylamine group having 2 to 10 carbon atoms, an arylamine group having 6 to 12 carbon atoms, and an aralkylamine group having 7 to 13 carbon atoms, a cyclic amine group having 3 to 10 carbon atoms, a heterocyclic amine group having 3 to 10 carbon atoms, and an alkyl silylamine group having 2 to 10 carbon atoms,

L is selected from a halogen atom, a hydrogen atom, or an azide group.

The doping precursor may be represented by any one of the following Chemical Formulas 16 to 21:

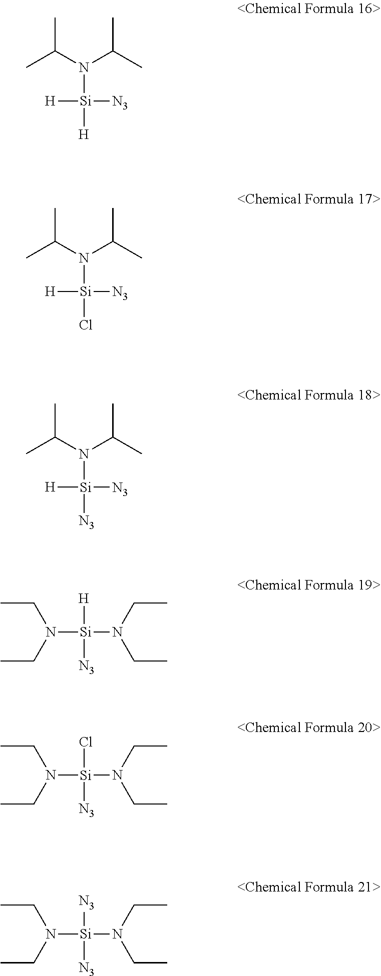

The doping precursor may be represented by the following Chemical Formula 22:

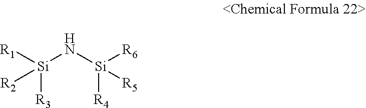

wherein R1 to R6 are each independently selected from a hydrogen atom, an alkyl group having 1 to 10 carbon atoms, an aryl group having 6 to 12 carbon atoms, an alkylamine group having 1 to 10 carbon atoms, an aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

The doping precursor may be represented by the following Chemical Formula 23:

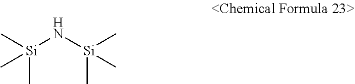

The doping precursor may be represented by the following Chemical Formula 24:

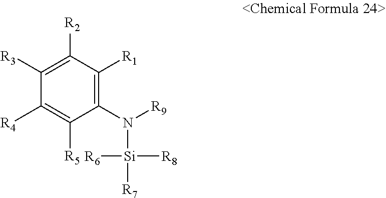

wherein R1 to R5 are each independently selected from a hydrogen atom, and an alkyl group having 1 to 4 carbon atoms,

R6 to R9 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

The doping precursor may be represented by any one of the following Chemical Formulas 25 to 27:

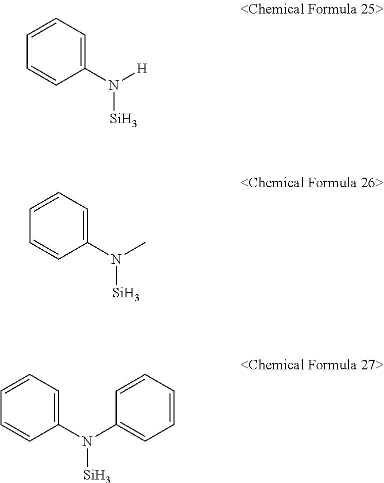

The doping precursor may be represented by the following Chemical Formula 28:

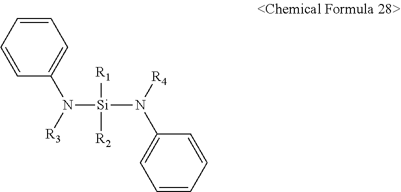

wherein R1 to R4 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

The doping precursor may be represented by the following Chemical Formula 29:

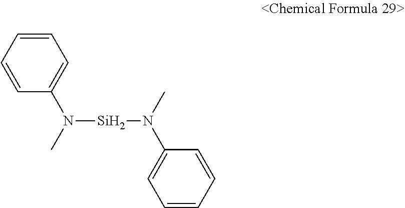

For example, the doping precursor cannot be adsorbed at the position where the surface protection material is adsorbed. In other words, the surface protection material prevents the adsorption of the doping precursor.

Thereafter, a purge gas (for example, an inert gas such as Ar) is supplied to the interior of the chamber to discharge the unadsorbed doping precursor or by-products.

Thereafter, the substrate is exposed to a reactant supplied to the interior of the chamber, and a doping thin film is formed on the surface of the substrate. The reactant reacts with the doping precursor to form the doping thin film, and the reactant may be selected from O₃, O₂, H₂O, H₂O₂, N₂O, and NH₃.

Thereafter, a purge gas (for example, an inert gas such as Ar) is supplied to the interior of the chamber to discharge the unreacted material or by-products.

Thereafter, the substrate is exposed to a dielectric film precursor supplied to the interior of the chamber, and the dielectric film precursor is adsorbed on the surface of the substrate. The dielectric film precursor may be a compound including at least one of a tetravalent metal containing Ti, Zr, and Hf.

Thereafter, a purge gas (for example, an inert gas such as Ar) is supplied to the interior of the chamber to discharge the unadsorbed dielectric film precursor or by-products.

Thereafter, the substrate is exposed to a reactant supplied to the interior of the chamber, and a dielectric film is formed on the surface of the substrate. The reactant reacts with the dielectric film precursor to form the dielectric film, and the reactant may be selected from O₃, O₂, H₂O, H₂O₂, N₂O, and NH₃.

Thereafter, a purge gas (for example, an inert gas such as Ar) is supplied to the interior of the chamber to discharge the unreacted material or by-products.

### Comparative Example 1

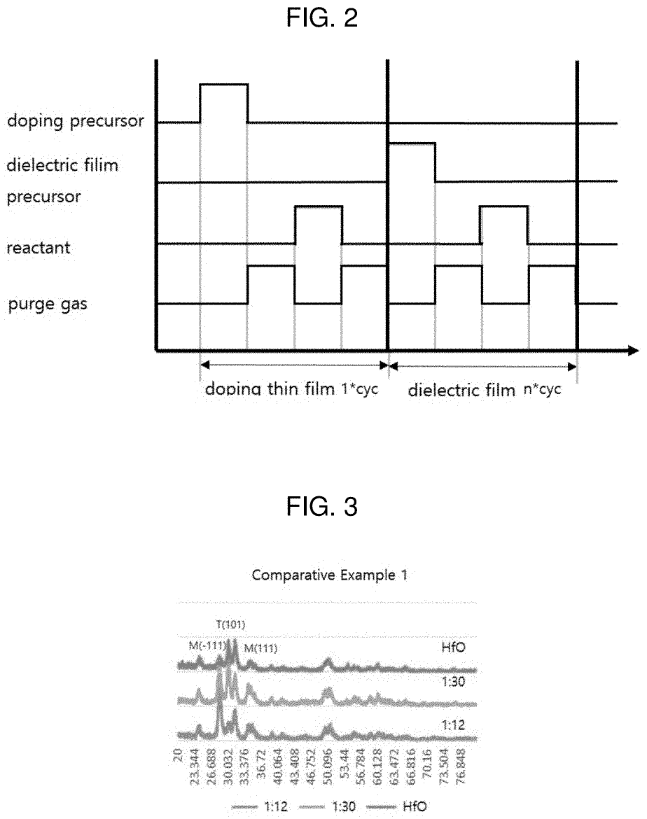

FIG. 2 is a graph schematically demonstrating a supply cycle according to the Comparative Example 1 of the present invention. A silicon oxide was formed as a doping thin film and a hafnium oxide was formed as a dielectric film, without using the surface protection material described above. Diisoprophylamino Silane (DIPAS) was used as a doping precursor to form the silicon oxide and tris(dimethylamino)cyclopentadienyl hafnium(IV)[CpHf(NMe2)3](HAC) was used as a dielectric film precursor, the process temperature was 320° C. and the reactant was O₃ gas).

The process of forming the thin film through the ALD process is as follows, and similar to the conventional doping method, the cycle ratios of silicon oxide and hafnium oxide are shown in Table 1 below. Table 1 shows the cycle ratio of SiO2 and HfO2 and XRD tetragonal phase ratio (%) according to the Comparative Example 1 and an embodiment 1, and the XRD Tetragonal phase ratio is calculated by T(101)/[(T101)+M(−111)+M(111)].

TABLE 1

| | | Tetragonal |
|---|---|---|
| Dep. Temp | Cycle ratio | phase |

| | (° C.) | SiO | HfO | ratio(%) |
|---|---|---|---|---|
| Comparative | 320 | 0 | 1 | 0.44 |
| Example 1 | | 1 | 12 | 0.173 |
| | | 1 | 30 | 0.408 |
| Embodiment | 320 | 0 | 1 | 0.44 |
| 1 | | 1 | 12 | 0.63 |
| | | 1 | 30 | 0.57 |

1) Ar is used as a carrier gas, the doping precursor (DIPAS) is supplied to the reaction chamber at room temperature, and the doping precursor is adsorbed onto the substrate.

2) Ar gas is supplied into the reaction chamber to discharge unadsorbed doping precursor or byproducts.

3) A doping thin film is formed by supplying ozone gas (O₃) to the reaction chamber.

4) Ar gas is supplied into the reaction chamber to discharge unreacted substances or by-products.

5) Ar is used as a carrier gas, the dielectric film precursor (HAC) is supplied to the reaction chamber at room temperature, and the dielectric film precursor is adsorbed onto the substrate.

6) Ar gas is supplied into the reaction chamber to discharge unadsorbed dielectric film precursor or byproducts.

7) A dielectric film is formed by supplying ozone gas (O₃) to the reaction chamber.

8) Ar gas is supplied into the reaction chamber to discharge unreacted substances or by-products.

FIG. 3 is an X-ray diffraction (XRD) result of the thin film according to the Comparative Example 1 of the present invention. When the Si ratio is low (1:30), the HfO and tetragonal ratios are similar. But, when the Si ratio increases (1:12), the tetragonal ratio decreases.

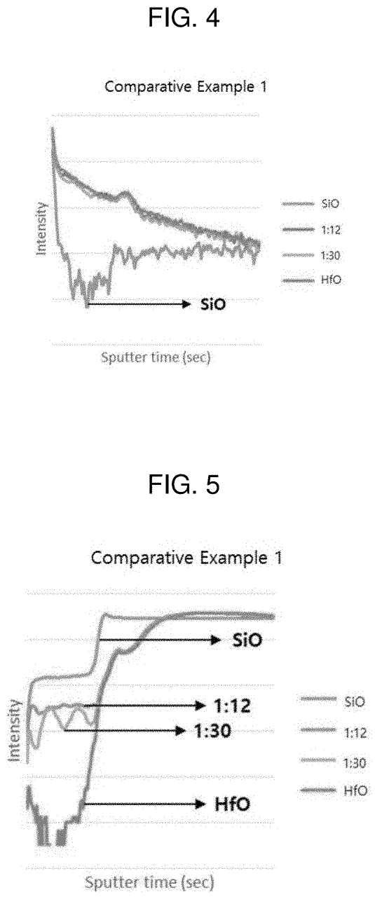

FIG. 4 is a graph demonstrating secondary ion mass spectrometry (SIMS) for carbon of the thin film according to the Comparative Example 1 of the present invention, FIG. 5 is a graph demonstrating secondary ion mass spectrometry (SIMS) for silicon of the thin film according to the Comparative Example 1 of the present invention. In the case of carbon impurity, it is at a similar level to that of HfO, and in the case of silicon, the Si peak intensity is at a similar level regardless of the Si cycle ratio.

### Embodiment 1

An aluminium oxide was formed on a silicon substrate using Trimethyl orthoformate as a surface protection material. A aluminium oxide was formed through the ALD process, the process temperature was 250 to 390° C., and the reactant was ozone gas (O₃).

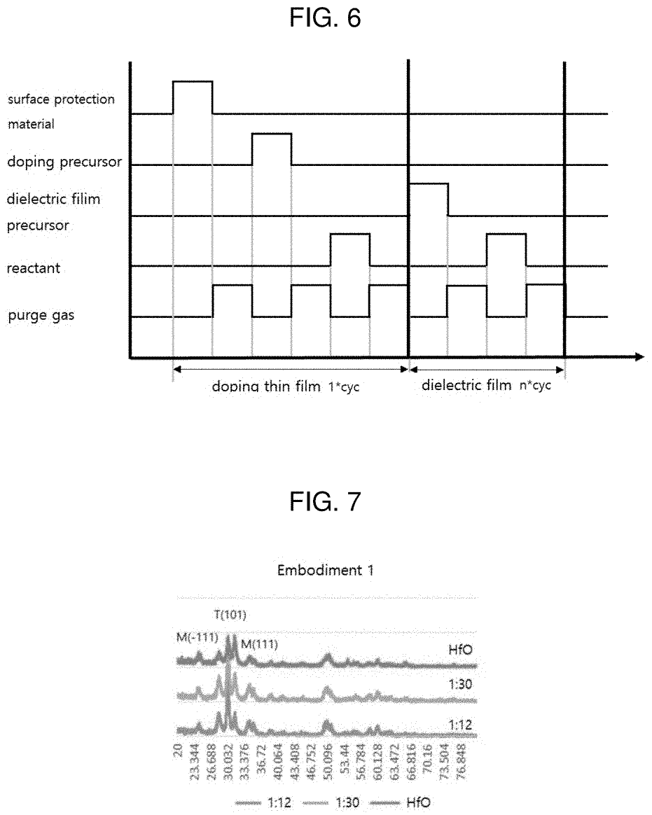

FIG. 6 is a graph schematically demonstrating a supply cycle according to the embodiment 1 of the present invention. The surface protection material is Trimethyl orthoformate, a silicon oxide was formed as a doping thin film and a hafnium oxide was formed as a dielectric film. Diisoprophylamino Silane (DIPAS) was used as a doping precursor to form the silicon oxide and tris(dimethylamino)cyclopentadienyl hafnium(IV)[CpHf(NMe2)3](HAC) was used as a dielectric film precursor, the process temperature was 320° C. and the reactant was O₃ gas).

The process of forming the thin film through the ALD process is as follows, and similar to the conventional doping method, the cycle ratios of silicon oxide and hafnium oxide are shown in Table 1 above.

1) A surface protection material is supplied to the reaction chamber to be adsorbed onto the substrate.

2) Ar gas is supplied into the reaction chamber to discharge unadsorbed surface protection materials or by-products.

3) Ar is used as a carrier gas, the doping precursor (DIPAS) is supplied to the reaction chamber at room temperature, and the doping precursor is adsorbed onto the substrate.

4) Ar gas is supplied into the reaction chamber to discharge unadsorbed doping precursor or byproducts.

5) A doping thin film is formed by supplying ozone gas (O₃) to the reaction chamber.

6) Ar gas is supplied into the reaction chamber to discharge unreacted substances or by-products.

7) Ar is used as a carrier gas, the dielectric film precursor (HAC) is supplied to the reaction chamber at room temperature, and the dielectric film precursor is adsorbed onto the substrate.

8) Ar gas is supplied into the reaction chamber to discharge unadsorbed dielectric film precursor or byproducts.

9) A dielectric film is formed by supplying ozone gas (O₃) to the reaction chamber.

10) Ar gas is supplied into the reaction chamber to discharge unreacted substances or by-products.

FIG. 7 is an X-ray diffraction (XRD) result of the thin film according to the embodiment 1 of the present invention. Regardless of the Si ratio, the ratio of the tetragonal phase (101) is larger than that of the monoclinic phase, and the deposition rate of SiO2 adsorbed due to the surface protection material is reduced. Therefore, it is estimated that the Si concentration is finely included to have an effect on the crystallinity improvement. As a result, when the same Si concentration is implemented, the tetragonal phase formation is facilitated without increasing the HfO2 matrix THK.

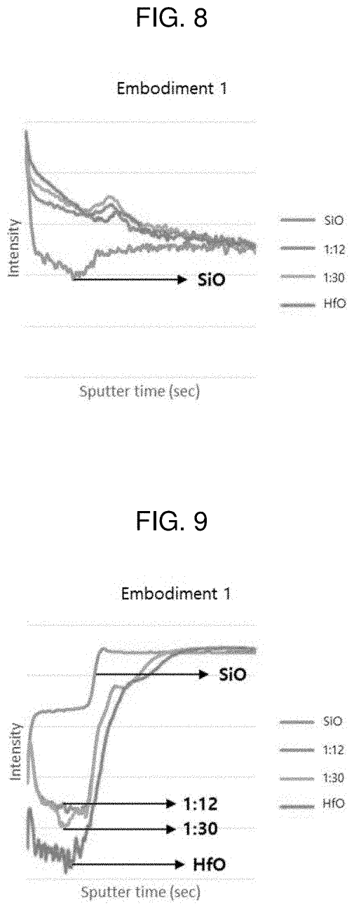

FIG. 8 is a graph demonstrating secondary ion mass spectrometry (SIMS) for carbon of the thin film according to the embodiment 1 of the present invention, FIG. 9 is a graph demonstrating secondary ion mass spectrometry (SIMS) for silicon of the thin film according to the embodiment 1 of the present invention. In the case of carbon impurity, it is at a similar level to HfO, and in the case of silicon, compared with the Comparative Example 1, it is decreased by more than 2 times, and the peak deviation is also reduced. By using the surface protection material, when forming the silicon oxide film, the deposition rate of the silicon oxide film can be lowered. Also, fine control of the Si concentration and reduction of peak deviation in the subsequently deposited dielectric film are is possible, thereby enabling a thin film of a desired composition and the formation of a uniform layer.

According to the present invention, the thickness of a doping thin film can be easily controlled through a low growth rate of the doping thin film, and a dielectric film having a desired composition can be obtained.

In addition, local compositional non-uniformity is alleviated, thereby obtaining a dielectric film having improved crystallinity and dielectric constant in the dielectric film.

The present invention has been explained in detail with reference to embodiments, but other embodiments may be included. Accordingly, the technical idea and scope described in the claims below are not limited to the embodiments.

1. A method of forming a thin film using a surface protection material, the method comprising:
supplying the surface protection material to the inside of a chamber on which a substrate is placed;
purging the interior of the chamber;
supplying a doping precursor to the inside of the chamber;
purging the interior of the chamber;
supplying a first reactant to the inside of the chamber so that the first reactant reacts with the adsorbed doping precursor to form a doping thin film;
supplying a dielectric film precursor to the inside of the chamber;
purging the interior of the chamber; and
supplying a second reactant to the inside of the chamber so that the second reactant reacts with the adsorbed dielectric film precursor to form a dielectric film.

2. The method of claim 1, wherein the surface protection material is represented by the following Chemical Formula 1: 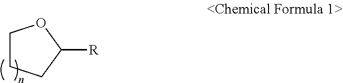
wherein n is 1 or 2, and R is selected from a hydrogen atom, an alkyl group having 1 to 5 carbon atoms, a cycloalkyl group having 3 to 6 carbon atoms, and an aryl group having 6 to 12 carbon atoms.

3. The method of claim 1, wherein the surface protection material is represented by the following Chemical Formula 2: 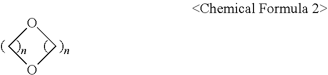
wherein n is each independently selected from an integer of 1 to 5.

4. The method of claim 1, wherein the surface protection material is represented by the following Chemical Formula 3: 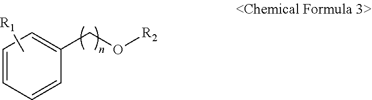
wherein n is each independently an integer from 0 to 8,
R1 is each independently selected from an alkyl group having 1 to 10 carbon atoms, an alkoxy group having 1 to 5 carbon atoms, or a hydrogen atom,
R2 is each independently selected from an alkyl group having 1 to 8 carbon atoms, a cycloalkyl group having 3 to 6 carbon atoms, and an aryl group having 6 to 12 carbon atoms.

5. The method of claim 1, wherein the surface protection material is represented by the following Chemical Formula 4: 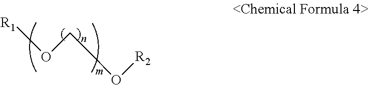
wherein n is each independently an integer from 1 to 8 and m is each independently an integer from 1 to 5,
R1 or R2 is each independently selected from an alkyl group having 1 to 8 carbon atoms, a cycloalkyl group having 3 to 6 carbon atoms, and an aryl group having 6 to 12 carbon atoms.

6. The method of claim 1, wherein the surface protection material is represented by the following Chemical Formula 5: 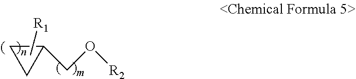
wherein n is each independently an integer from 1 to 5 and m is each independently an integer from 0 to 8,
R1 is each independently selected from an alkyl group having 1 to 8 carbon atoms, or a hydrogen atom,
R2 is each independently selected from an alkyl group having 1 to 8 carbon atoms, a cycloalkyl group having 3 to 6 carbon atoms, and an aryl group having 6 to 12 carbon atoms.

7. The method of claim 1, wherein the surface protection material is represented by the following Chemical Formula 6: 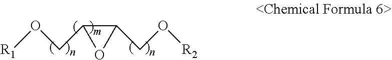
wherein n is each independently an integer from 1 to 8 and m is each independently an integer from 1 to 6,
R1 or R2 is each independently selected from an alkyl group having 1 to 8 carbon atoms, a cycloalkyl group having 3 to 6 carbon atoms, and an aryl group having 6 to 12 carbon atoms.

8. The method of claim 1, wherein the surface protection material is represented by the following Chemical Formula 7: 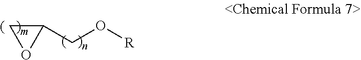
wherein n is each independently an integer from 0 to 5 and m is each independently an integer from 1 to 5,
R is each independently selected from an alkyl group having 1 to 10 carbon atoms, a cycloalkyl group having 3 to carbon atoms, and an aryl group having 6 to 12 carbon atoms.

9. The method of claim 1, wherein the surface protection material is represented by the following Chemical Formula 8: 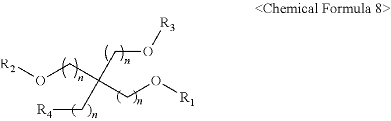
wherein n is each independently an integer from 0 to 8,
R1 to R3 are each independently selected from an alkyl group having 1 to 8 carbon atoms,
R4 is selected from a hydrogen, an alkyl group having 1 to 6 carbon atoms, and an alkoxy group having 1 to 8 carbon atoms.

10. The method of claim 1, wherein the doping precursor is represented by the following Chemical Formula 9: 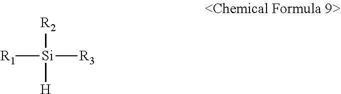
wherein R1 to R3 are each independently selected from a hydrogen atom, an alkyl group having 1 to 10 carbon atoms, an aryl group having 6 to 12 carbon atoms, an alkylamine group having 1 to 10 carbon atoms, a dialkyl amine group having 2 to 10 carbon atoms, aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

11. The method of claim 10, wherein the doping precursor is represented by any one of the following Chemical Formulas 10 to 14:

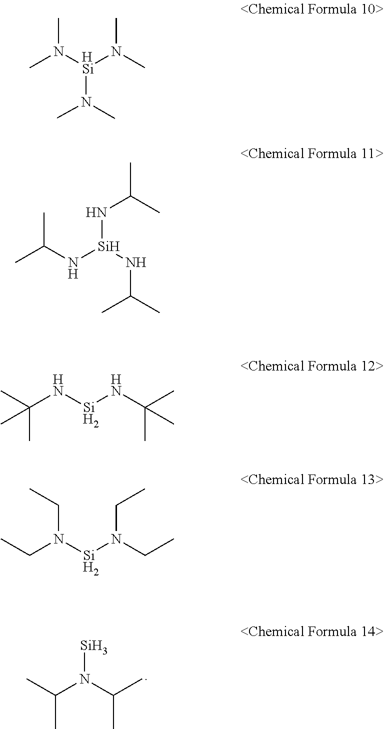

12. The method of claim 1, wherein the doping precursor is represented by the following Chemical Formula 15: 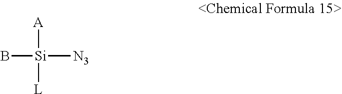
wherein A and B are each independently selected from a hydrogen atom, a halogen atom, an alkyl group having 1 to 10 carbon atoms, an aryl group having 6 to 12 carbon atoms, an alkylamine group having 2 to 10 carbon atoms, an arylamine group having 6 to 12 carbon atoms, and an aralkylamine group having 7 to 13 carbon atoms, a cyclic amine group having 3 to 10 carbon atoms, a heterocyclic amine group having 3 to 10 carbon atoms, and an alkyl silylamine group having 2 to 10 carbon atoms,
L is selected from a halogen atom, a hydrogen atom, or an azide group.

13. The method of claim 12, wherein the doping precursor is represented by any one of the following Chemical Formulas 16 to 21:

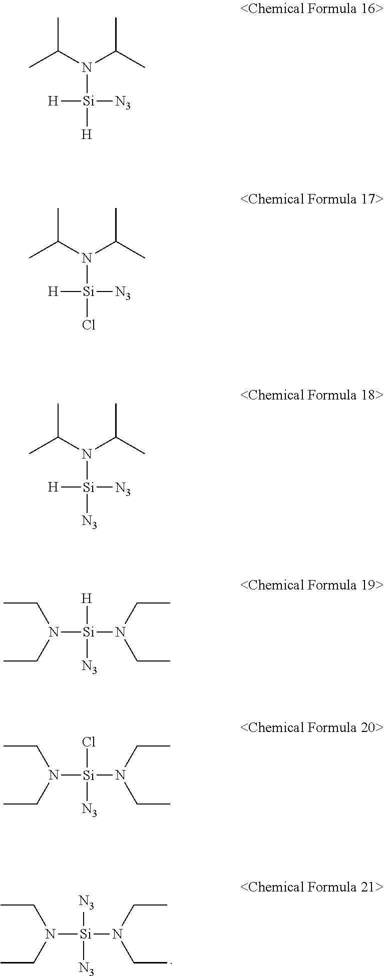

14. The method of claim 1, wherein the doping precursor is represented by the following Chemical Formula 22: 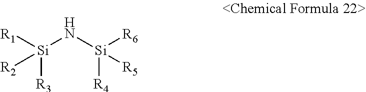
wherein R1 to R6 are each independently selected from a hydrogen atom, an alkyl group having 1 to 10 carbon atoms, an aryl group having 6 to 12 carbon atoms, an alkylamine group having 1 to 10 carbon atoms, an aryl amine group having 6 to 12 carbon atoms, an aralkylamine group having 7 to 13 carbon atoms, a cyclic amine group having 3 to 10 carbon atoms, a heterocyclic amine group having 3 to 10 carbon atoms, a heteroarylamine group having 6 to 12 carbon atoms, or an alkyl silylamine group having 2 to 10 carbon atoms.

15. The method of claim 14, wherein the doping precursor is represented by the following Chemical Formula 23:

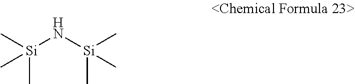

16. The method of claim 1, wherein the doping precursor is represented by the following Chemical Formula 24: 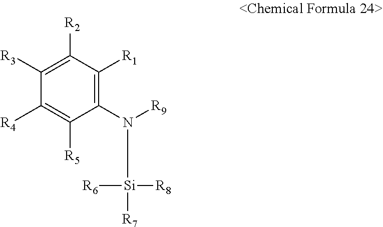
wherein R1 to R5 are each independently selected from a hydrogen atom, and an alkyl group having 1 to 4 carbon atoms,
R6 to R9 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

17. The method of claim 16, wherein the doping precursor is represented by any one of the following Chemical Formulas 25 to 27:

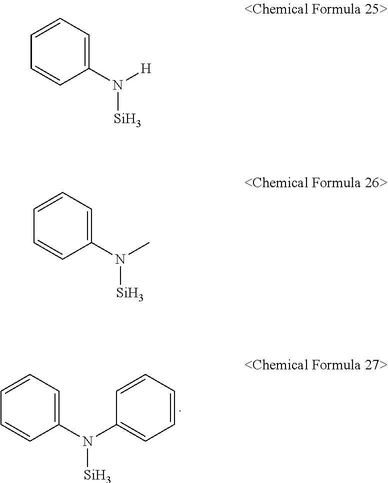

18. The method of claim 1, wherein the doping precursor is represented by the following Chemical Formula 28: 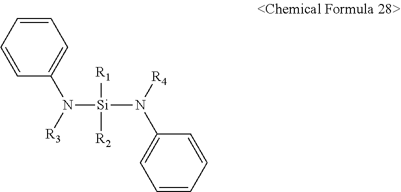
wherein R1 to R4 are each independently selected from a hydrogen atom, and an alkyl group having 1 to 4 carbon atoms, an alkylamine group having 1 to 4 carbon atoms, a dialkyl amine group having 2 to 4 carbon atoms, and an aryl group having 6 to 12 carbon atoms.

19. The method of claim 18, wherein the doping precursor is represented by the following Chemical Formula 29:

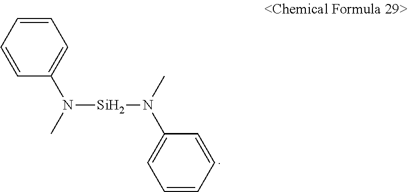

20. The method of claim 1, wherein the first reactant and the second reactant are selected from O₃, O₂, H₂O, H₂O₂, N₂O, and NH₃.

21. The method of claim 1, wherein the dielectric film precursor is a compound including at least one of a tetravalent metal containing Ti, Zr, and Hf.
